(19) United States
(12) Patent Application Publication
(10) Pub. No.: US 2023/0333749 A1
(43) Pub. Date: Oct. 19, 2023

(54) MEMORY, OPERATION METHOD OF MEMORY, AND OPERATION METHOD OF MEMORY SYSTEM

(71) Applicant: SK hynix Inc., Gyeonggi-do (KR)

(72) Inventors: Munseon JANG, Gyeonggi-do (KR); Hoiju Chung, San Jose, CA (US)

(21) Appl. No.: 17/883,096

(22) Filed: Aug. 8, 2022

Related U.S. Application Data
(60) Provisional application No. 63/331,634, filed on Apr. 15, 2022.

(51) Int. Cl. G06F 3/06

(52) U.S. Cl. CPC G06F 3/0619; G06F 3/0655; G06F 3/0673

(57) ABSTRACT

A method for operating a memory includes: a first region error checking operation of reading data of N memory cells from each of K, rows, where K is an integer equal to or greater than 2, by using N first bit line sense amplifiers, where N is an integer equal to or greater than 2 and checking errors; processing first region error information based on the number of errors detected in the first region error checking operation; a second region error checking operation of reading data of N memory cells in each of K rows by using N second bit line sense amplifiers and checking errors; and processing second region error information based on the number of errors detected in the second region error checking operation.

### CROSS-REFERENCE TO RELATED APPLICATIONS

The present application claims the benefit of U.S. Provisional Patent Application No. 63/331,634, filed on Apr. 15, 2022, which is incorporated herein by reference in its entirety.

### BACKGROUND

### 1. Field

Various embodiments of the present invention relate to a memory.

### 2. Description of the Related Art

In the early stage of the semiconductor memory device industry, there were many originally good dies on the wafers, which means that memory chips were produced with no defective memory cells through a semiconductor fabrication process. However, as the capacity of memory devices increases, it becomes difficult to fabricate a memory device that does not have any defective memory cell, and nowadays, it may be said that there are substantially no chances that a memory device is fabricated without any defective memory cells. To address the issue, a repair method of including redundant memory cells in a memory device and replacing defective memory cells with the redundant memory cells is being used.

In another method, an error correction circuit (ECC circuit) for correcting errors in a memory system is used to correct errors occurring in memory cells and errors occurring when data are transferred during a read operation and a write operation of the memory system.

### SUMMARY

Embodiments of the present invention are directed to a method of checking errors in a memory.

In accordance with an embodiment of the present invention, a method for operating a memory includes: a first region error checking operation of reading first data from N memory cells in each of K rows by using N first bit line sense amplifiers and checking errors from the first data, each of K and N being an integer equal to or greater than 2; processing first region error information based on a number of the checked errors from the first data; a second region error checking operation of reading second data from N memory cells in each of K rows by using N second bit line sense amplifiers and checking errors from the second data; and processing second region error information based on the number of checked errors from the second data.

In accordance with another embodiment of the present invention, a memory includes: a cell array including a plurality of memory cells and including a plurality of bit line sense amplifiers, the memory cells being arranged in a plurality of rows and a plurality of columns and being grouped into a plurality of regions, and the bit line sense amplifiers suitable for sensing and amplifying data of the memory cells; an error detection circuit suitable for detecting an error in data read from each of the regions; and an error counting circuit suitable for counting a number of detected errors, wherein each of the regions includes: N bit line sense amplifiers, where N is an integer equal to or greater than 2; and memory cells in which data is sensed and amplified by the N bit line sense amplifiers.

In accordance with yet another embodiment of the present invention, a method for operating a memory system includes: providing, by a memory controller, a memory with information on an off-lined region; and performing, by the memory, an error check and scrub operation while changing regions except for the off-lined region among a plurality of regions in the memory.

The method may further comprise: performing, by the memory, the error check and scrub operation while changing regions for all regions in the memory; providing, by the memory, the memory controller with information about a bad region in which a number of detected errors is equal to or greater than a threshold value as a result of the error check and scrub operation; and off-lining, by the memory controller, the bad region to generate the information on the off-lined region.

In accordance with still another embodiment of the present invention, a method for operating a memory includes: receiving an address of an off-lined region from a memory controller; storing the address of the off-lined region; generating a first address for a first region; confirming that the first address is different from the address of the off-lined region; performing the error check and scrub operation on the first region; generating a second address for a second region; confirming that the second address and the address of the off-lined region are the same; and skipping the error check and scrub operation on the second region.

In accordance with still another embodiment of the present invention, a memory includes: a cell array including a plurality of regions each including a plurality of memory cells; an off-lined region storing circuit suitable for storing information of an off-lined region, the information being transferred from a memory controller; an error detection circuit suitable for detecting one or more errors in data read from each of the regions; an error counting circuit suitable for counting a number of the detected errors; an error log circuit suitable for storing a result of the counting; and a blocking circuit suitable for preventing the error logic circuit from storing the result of a region which is the same as the off-lined region among the regions.

Wherein the result may include information of a region, of which the number of the detected errors is equal to or greater than a threshold value.

Wherein the result may include: the number of the detected errors of each of the regions.

In accordance with still another embodiment of the present invention, a memory includes: a cell array including a plurality of regions each including a plurality of memory cells; an off-lined region storing circuit suitable for storing information of an off-lined region, the information being transferred from a memory controller; an error detection circuit suitable for detecting one or more errors in data read from each of the regions; an error counting circuit suitable for counting a number of the detected errors; an error log circuit suitable for storing a result of the counting; and a blocking circuit suitable for preventing the error counting circuit from counting the detected errors of a region which is the same as the off-lined region among the regions.

Wherein the result may include information of a region, of which the number of the detected errors is equal to or greater than a threshold value.

Wherein the result may include the number of the detected errors for each of the regions.

In accordance with still another embodiment of the present invention, a method for operating a memory includes: counting a number of errors detected from data read from a region; and determining, based on the number, the region as a bad region to skip the counting to be performed subsequently on the bad region, wherein the memory system includes first and second arrays, each of which is configured by columns of memory cells, and wherein the region is a part of the columns within both the first and second arrays, the part being selected at a time and simultaneously accessible by a single column address.

### BRIEF DESCRIPTION OF THE DRAWINGS

FIG. 1 is a block diagram illustrating a memory system 100 in accordance with an embodiment of the present invention.

FIG. 2 is a block diagram illustrating a memory 120 shown in FIG. 1 in accordance with an embodiment of the present invention.

FIG. 3 is a flowchart describing an operation of the memory system 100 described in FIGS. 1 and 2 in accordance with an embodiment of the present invention.

FIG. 4 illustrates a cell array 271 shown in FIG. 2 in accordance with an embodiment of the present invention.

### DETAILED DESCRIPTION

Various embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout this disclosure, like reference numerals refer to like parts throughout the various figures and embodiments of the present invention.

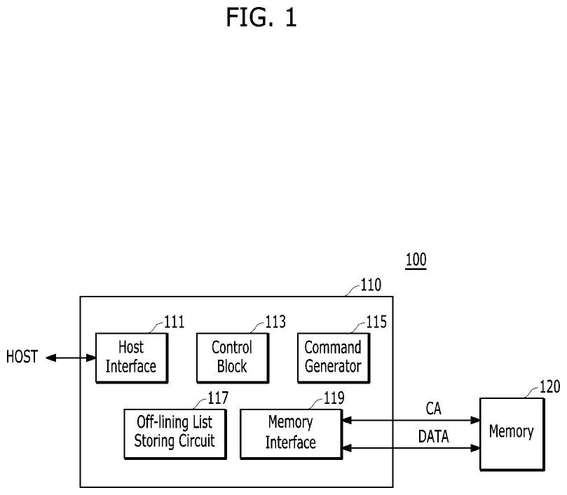

FIG. 1 is a block diagram illustrating a memory system 100 in accordance with an embodiment of the present invention.

The memory controller 110 may control the operation of a memory 120 according to a request of a host HOST. The host HOST may include a central processing unit (CPU), a graphic processing unit (GPU), an application processor (AP), and the like. The memory controller 110 may include a host interface 111, a control block 113, a command generator 115, an off-lined list storing circuit 117, and a memory interface 119. The memory controller 110 may be included in a CPU, GPU, AP, etc. In this case, the host HOST may mean the structures other than the memory controller 110 in the CPU, GPU, AP, etc. For example, when the memory controller 110 is included in a CPU, the host HOST in the figure may represent the other constituent elements except for the memory controller 110 in the CPU.

The host interface 111 may be an interface for communication between the host HOST and the memory controller 110.

The control block 113 may control the overall operations of the memory controller 110 and may schedule the operations to be commanded to the memory 220. The control block 113 may change the order of the requests received from the host HOST and the order of operations to be commanded to the memory 120 in order to improve the performance of the memory 120. For example, even though the host HOST requests the memory 120 to perform a read operation first and then to perform a write operation later, the control block 113 may change the order so that the memory 120 may perform a write operation before a read operation.

The command generator 115 may generate a command to be applied to the memory 120 according to the order of operations which is determined by the control block 113.

The memory interface 119 may be provided for an interface between the memory controller 110 and the memory 120. A command and an address CA may be transferred from the memory controller 110 to the memory 120 through the memory interface 119, and data DATA may be transferred/received through the memory interface 119. The memory interface 119 may also be referred to as a PHY interface.

The memory controller 110 may control the memory 120 in an error check operation mode. When the control block 113 determines to operate the memory 120 in an error check and scrub operation mode, the command generator 115 may generate a command for controlling the memory 120 in the error check and scrub operation mode and the memory interface 119 may transfer the command generated by the command generator 115 to the memory 120. Furthermore, the memory controller 110 may request the memory 120 for information about bad regions collected during an error check and scrub operation of the memory 120 and may receive the information about the bad regions from the memory 120.

The memory controller 110 may do off-line a bad region that meets a condition among the bad regions of the information which is received from the memory 120. The memory controller 110 may no longer access the off-lined region. In this disclosure, “do off-line a region” means to identify the region in order not to access the region thereafter. The memory controller 110 may off-line all the bad regions, or it may off-line the bad regions whose number of errors is equal to or greater than a reference value which is determined by the memory controller among the bad regions. The list of the off-lined regions may be stored in the off-lined list storing circuit 117.

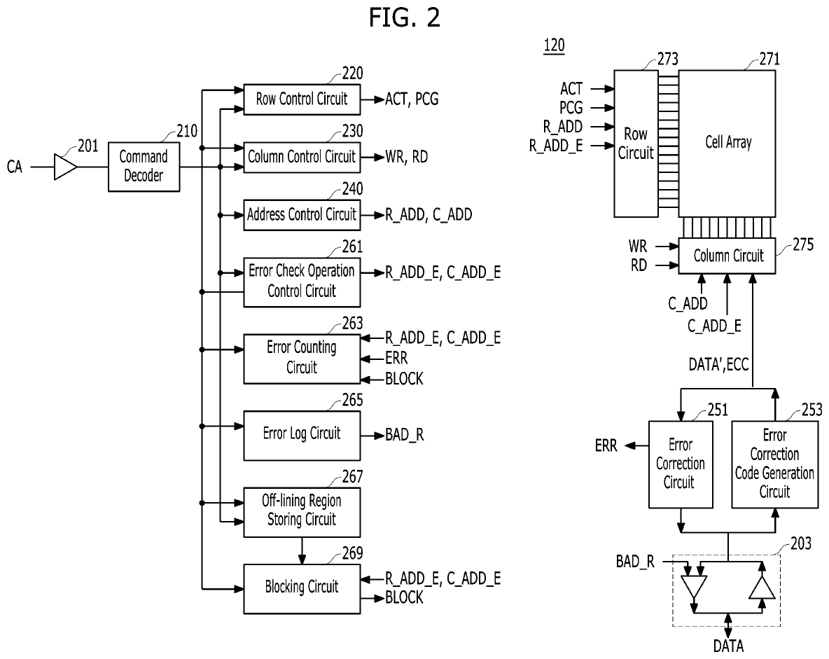

The memory 120 may perform an operation commanded by the memory controller 110. The memory 120 will be described later in detail with reference to FIG. 2.

FIG. 2 is a block diagram illustrating a memory 120 shown in FIG. 1 in accordance with an embodiment of the present invention.

Referring to FIG. 2, the memory 120 may include a command address receiving circuit 201, a data transferring/receiving circuit 203, a command decoder 210, a row control circuit 220, a column control circuit 230, an address control circuit 240, an error correction circuit 251, an error correction code generation circuit 253, an error check operation control circuit 261, an error counting circuit 263, an error log circuit 265, an off-lined region storing circuit 267, a blocking circuit 269, a cell array 271, a row circuit 273, and a column circuit 275.

The command address receiving circuit 201 may receive a command and an address CA. Depending on the type of the memory 120, a command and an address may be input to the same input terminals, or the command and the address may be input to separate input terminals. Herein, it is illustrated that the command and the address are input to the same terminals. The command and the address CA may be multiple bits.

The data transferring/receiving circuit 203 may receive data DATA or transfer data DATA. The data transferring/receiving circuit 203 may receive data DATA to be written into the cell array 271 during a write operation, and may transfer data DATA that are read from the cell array 271 during a read operation.

The command decoder 210 may decode the command and the address CA to find out the type of an operation commanded by the memory controller 110 to the memory 120.

When it is found out as a result of the decoding in the command decoder 210 that a row-based operation such as an active operation and a precharge operation is commanded, the row control circuit 220 may control these operations. An active signal ACT may be a signal commanding an active operation, and a precharge signal PCG may be a signal commanding a precharge operation.

When it is found out as a result of the decoding in the command decoder 210 that a column-based operation such as a write operation and a column operation is commanded, the column control circuit 230 may control these operations. A write signal WR may be a signal commanding a write operation, and a read signal RD may be a signal commanding a read operation.

Moreover, when it is found out as a result of the decoding in the command decoder 210 that an error check and scrub operation mode is commanded, the memory 120 may operate in an error check and scrub operation mode. In the error check and scrub operation mode, the memory 120 may operate under the control of the error check operation control circuit 261.

The address control circuit 240 may determine the address received from the command decoder 210 as a row address R_ADD or a column address C_ADD and transfer it to the row circuit 273 or the column circuit 275. When it is found out as a result of the decoding in the command decoder 210 that an active operation is commanded, the address control circuit 240 may determine the received address as a row address R_ADD. On the other hand, when read and write operations are commanded, the address control circuit 240 may determine the received address as a column address C_ADD.

The error correction circuit 251 may correct an error in data DATA′ read from the cell array 271 based on an error correction code ECC which is read from the cell array 271 during a read operation. Here, correcting an error may mean detecting an error in the data DATA′ and correcting the detected error in the data DATA′. The error correction circuit 251 may detect and correct an error in the error correction code ECC as well as the error in the data DATA′. When an error in the data DATA′ is detected and the error is corrected, the data DATA′ input to the error correction circuit 251 and data DATA output from the error correction circuit 251 may be different from each other. An error signal ERR may be a signal that is activated when an error is detected by the error correction circuit 251.

The error correction code generation circuit 253 may generate an error correction code ECC based on the data DATA during a write operation. During the write operation, the error correction code ECC may be generated based on the data DATA, but the error of the data DATA is not corrected. Therefore, the data DATA input to the error correction code generation circuit 253 and the data DATA output from the error correction code generation circuit 253 may be the same.

The error check operation control circuit 261 may control an error check and scrub operation. The error check and scrub operation may also be referred to as an ECS (Error Check and Scrub) operation, and it may mean an operation of selecting a region with many errors by reading the data DATA′ from the cell array 271 and checking the errors of the data DATA′ by using the error correction circuit 251. The error check operation control circuit 261 may control the error check and scrub operation when the error check and scrub operation mode is set. During the error check and scrub operation, it is necessary to control a row operation and a column operation. Therefore, the error check operation control circuit 261 may control the row control circuit 220 and the column control circuit 230 during the error check and scrub operation. Also, the error check operation control circuit 261 may control the error counting circuit 263, the error log circuit 265, the off-lined region storing circuit 267, and the blocking circuit 269, which are related to the error check and scrub operation.

The error check operation control circuit 261 may generate error check addresses R_ADD_E and C_ADD_E to be used for an error check and scrub operation. The error check addresses R_ADD_E and C_ADD_E may include an error check row address R_ADD_E and an error check column address C_ADD_E. The error check operation control circuit 261 may change the error check addresses R_ADD_E and C_ADD_E for each error check and scrub operation. The error check operation control circuit 261 may increase the error check addresses R_ADD_E and C_ADD_E by one step whenever an error check operation is performed. When the value of the error check row address R_ADD_E ranges from 0 to X and the value of the error check column address C_ADD_E ranges from 0 to Y, the error check address generation circuit 263 may generate the error check addresses R_ADD_E and C_ADD_E as (0, 0) during a first error check and scrub operation. Also, during a second error check and scrub operation, the error check operation control circuit 261 may increase the error check addresses R_ADD_E and C_ADD_E by one step to generate the error check addresses R_ADD_E and C_ADD_E as (0, 1). Similarly, during a third error check and scrub operation, the error check operation control circuit 261 may increase the error check addresses R_ADD_E and C_ADD_E by one step to generate the error check addresses R_ADD_E and C_ADD_E as (0, 2). The error check addresses R_ADD_E and C_ADD_E may be increased by one step whenever an error check and scrub operation is performed, and the error check addresses R_ADD_E and C_ADD_E may be generated differently every time: (0, 0)→(0, 1)→(0, 2)→ . . . →(0, Y−1)→(0, Y)→(1, 0)→(1, 1)→ . . . →(1, Y−1)→(1, Y)→(2, 0)→(2, 1)→ . . . →(X, Y−1)→(X, Y). Since the error check operation control circuit 261 changes the error check addresses R_ADD_E and C_ADD_E whenever an error check and scrub operation is performed, when the error check and scrub operation is repeatedly performed, the error check and scrub operation may be performed for all memory cells of the cell array 271.

The error counting circuit 263 may count the number of errors that are detected during an error check and scrub operation for each region of the cell array 271. Herein, the regions may be rows. That is, the error counting circuit 263 may count the number of errors for each of the cell array 271. Since the error counting circuit 263 receives the error check addresses R_ADD_E and C_ADD_E and an error signal ERR, it is possible to check where in the cell array 271 an error check and scrub operation is performed and whether an error is detected or not.

The error log circuit 265 may process and store the counting result of the error counting circuit 263. The error log circuit 265 may store information of a region in which the number of errors counted by the error counting circuit 263 is equal to or greater than a threshold value. In this case, the region stored in the error log circuit 265 may be classified as a bad region. Alternatively, the error log circuit 265 may store all counting results of the error counting circuit 263. The error log circuit 265 may store the counting results of all regions that are counted by the error counting circuit 263. In this case, a region having the most errors among the regions stored in the error log circuit 265 may be classified as a bad region.

When there is a request from the memory controller 110, bad region information BAD_R stored in the error log circuit 265 may be transferred to the memory controller 110. The bad region information BAD_R may be transferred from the memory 120 to the memory controller 110 through the data transferring/receiving circuit 203.

The off-lined region storing circuit 267 may store a region which is off-lined by the memory controller 110. The memory controller 110 may transfer information of the off-lined regions that it has off-lined and stored in the off-lined list storing circuit 117 to the memory 120. The information of the off-lined regions may be stored in the off-lined region storing circuit 267 of the memory 120. The information of the regions off-lined by the memory controller 110 may be transferred to the memory 120 in the form of a command and an address CA, and transferred to the off-lined region storing circuit 267 through the command decoder 210 to be stored.

The blocking circuit 269 may prevent an error check and scrub operation from being performed on a region stored in the off-lined region storing circuit 267. This is to prevent a region which is already off-lined from being continuously classified as a bad region, and it is no longer necessary to perform an error check and scrub operation on the region which is already off-lined. When the region where the error check and scrub operation is being performed is an off-lined region, the blocking circuit 269 may activate a blocking signal BLOCK and prevent the error counting circuit 263 from counting the errors of the corresponding region. Although the figure shows that the error counting of the error counting circuit 263 is prevented based on the blocking signal BLOCK, the blocking circuit 269 may be used to prevent the storing operation of the error log circuit 265. The error counting result of the region which is already off-lined may not be stored in the error log circuit 265. Since the blocking circuit 269 receives the error check addresses R_ADD_E and C_ADD_E as inputs, it is possible to determine whether or not the region where the error check and scrub operation is being performed currently corresponds to a region stored in the off-lined region storing circuit 267.

The cell array 271 may include a plurality of memory cells that are arranged in a plurality of rows and a plurality of columns. In the cell array 271, the row lines arranged in a row direction may be called word lines, and the column lines arranged in a column direction may be called bit lines. Each of the memory cells may be coupled to one of the row lines and one of the column lines.

When the active signal ACT is activated, the row circuit 273 may activate a row which is selected based on a row address R_ADD among the rows of the cell array 271. Also, in the error check mode, that is, during an error check and scrub operation, when the active signal ACT is activated, the row circuit 273 may activate a row which is selected based on an error check row address R_ADD_E among the rows of the cell array 271.

When a write signal WR is activated, the column circuit 275 may write data into the memory cells of the columns that are selected based on a column address C_ADD among the columns of the cell array 271. When a read signal RD is activated, the column circuit 275 may read data from the memory cells of the columns that are selected based on the column address C_ADD among the columns of the cell array 271. Also, in the error check mode, that is, during an error check and scrub operation, the column circuit 275 may use an error check column address C_ADD_E instead of the column address C_ADD. During the error check and scrub operation, a read operation may be performed on the memory cells of the columns that are selected based on the error check column address C_ADD_E.

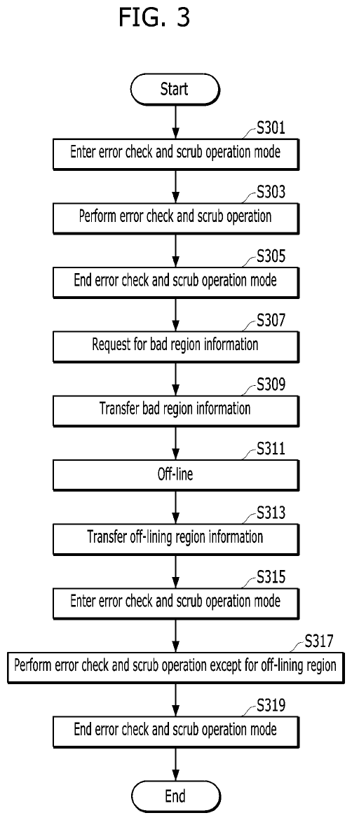

FIG. 3 is a flowchart describing an operation of the memory system 100 described in FIGS. 1 and 2 in accordance with an embodiment of the present invention.

Referring to FIG. 3, first, the memory 120 may enter an error check and scrub operation mode in operation S301. When the memory controller 110 commands the memory 120 to enter the error check and scrub operation mode based on the command and the address CA, the memory 120 may enter the error check and scrub operation mode.

The memory 120 may now perform an error check and scrub operation in operation S303. During the error check and scrub operation, data may be read from the memory cells corresponding to the error check addresses R_ADD_E and C_ADD_E that are generated by the error check operation control circuit 261, and the data DATA′ read by the error correction circuit 251 may be checked for errors, and the number of errors may be counted by the error counting circuit 263 for each region, and the counting result of the error counting circuit 263 may be stored in the error log circuit 265. These operations may be repeated while changing the error check addresses R_ADD_E and C_ADD_E.

The error check and scrub operation of the memory 120 may be terminated in operation S305. When the memory controller 110 commands the memory 120 to end the error check and scrub operation mode based on the command and the address CA, the error check and scrub operation mode of the memory 120 may end.

The memory controller 110 may request the memory 120 for bad region information collected as a result of the error check and scrub operation in operation S307. When the memory controller 110 requests bad region information based on the command and the address CA, the memory 120 may transfer the bad region information BAD_R stored in the error log circuit 265 to the memory controller 110 in response to the request from the memory controller 110 in operation S309.

The memory controller 110 may off-line the bad region transferred from the memory 120 and store the off-lined region in the off-lined list storing circuit 117 in operation S311. Thereafter, the memory controller 110 may not access the off-lined region in the memory 120.

The memory controller 110 may transfer information of the off-lined region to the memory 120 in operation S313. The memory controller 110 may inform the memory 120 of which region it has off-lined by using the command and the address CA, and the memory 120 may store the region off-lined by the memory controller 110 in the off-lined region storing circuit 267.

The memory 120 may enter the error check and scrub operation mode again in operation S315. When the memory controller 110 commands the memory 120 to enter the error check and scrub operation mode by using the command and the address CA, the memory 120 may enter the error check and scrub operation mode.

The memory 120 may perform an error check and scrub operation on the regions other than the off-lined region in operation S317. During the error check and scrub operation, data may be read from the memory cells corresponding to the error check addresses R_ADD_E and C_ADD_E generated by the error check operation control circuit 261, and the data DATA′ read by the error correction circuit 251 may be checked for errors, and the number of errors may be counted by the error counting circuit 263 for each region, and the counting result of the error counting circuit 263 may be stored in the error log circuit 265. These operations may be repeated while changing the error check addresses R_ADD_E and C_ADD_E. However, when the region in which the error check operation is being performed is the same as the region stored in the off-lined region storing circuit 267, the blocking circuit 269 may prevent the operations of the error counting circuit 263 or the error log circuit 265. Therefore, an error check and scrub operation may not be performed on an off-lined region.

The error check and scrub operation of the memory 120 may be terminated in operation S319. When the memory controller 110 commands the memory 120 to terminate the error check and scrub operation mode by using the command and the address CA, the error check and scrub operation mode of the memory 120 may end.

According to the embodiment of the present disclosure described above, the bad region detected as a result of the error check and scrub operation of the memory 120 may be off-lined by the memory controller 110, and then in the subsequent error check and scrub operations of the memory 120, the error check and scrub operation may be performed only on the regions except for the off-lined region. Therefore, it is possible to prevent unnecessary error check and scrub operations and to classify a region with an error from being repeatedly classified as a bad region.

In the embodiment of the present disclosure described above, it is illustrated that the number of errors is counted during an error check and scrub operation and the regions classified as bad regions are rows. Namely, one region is illustrated as one row. However, differently from this, the regions may be classified based on the columns, which will be described below.

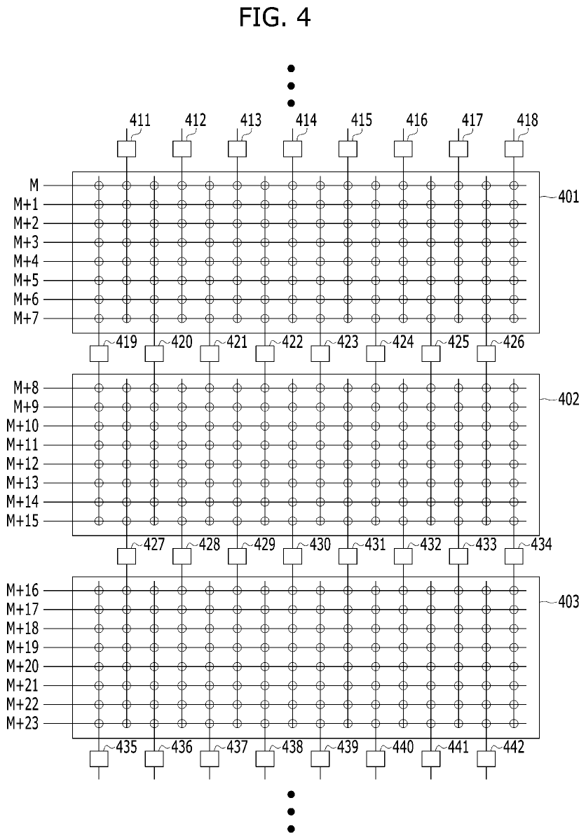

FIG. 4 illustrates the cell array 271 shown in FIG. 2 in accordance with an embodiment of the present invention.

Referring to FIG. 4, the cell array 271 may include a plurality of sub-cell arrays 401, 402 and 403 and bit line sense amplifiers 411 to 442 between the sub-cell arrays 401, 402 and 403. The circles at the intersection between the row lines and the column lines may represent memory cells. Each of the bit line sense amplifiers 411 to 442 may be coupled to K memory cells, where K is an integer equal to or greater than 2, and the bit line sense amplifiers 411 to 442 may be simultaneously coupled to N bit line sense amplifiers 411 to 442 during one read or write operation, where N is an integer equal to or greater than 2. For the sake of convenience in description, each of the sub-cell arrays 401 to 402 includes eight rows. Namely, K=16. Accordingly, FIG. 4 shows 32 rows M to M+23. Also, there are only four values of 0 to 3 for the value of the column address C_ADD or C_ADD_E. Also, four columns are simultaneously accessed during one read or write operation. That is, N=4.

Each of the bit line sense amplifiers 411 to 442 may sense and amplify the data of a memory cell which is selected among the memory cells of an upper sub-cell array and a lower sub-cell array. For example, the bit line sense amplifier 419 may sense and amplify the data of a memory cell which is selected among 8 memory cells coupled thereto in the sub-cell array 401 and 8 memory cells coupled thereto in the sub-cell array 402. Also, the bit line sense amplifier 431 may sense and amplify the data of a memory cell selected among 8 memory cells coupled thereto in the sub-cell array 402 and 8 memory cells coupled thereto in the sub-cell array 403.

When the row M+10 of the sub-cell array 402 is activated and the value of the column address C_ADD or C_ADD_E is 0, the bit line sense amplifiers 419, 421, 423, and 425 may be selected. In this case, four memory cells coupled to the bit line sense amplifiers 419, 421, 423, and 425 may be accessed in the row M+10. When the value of the column address C_ADD or C_ADD_E is 1, the bit line sense amplifiers 427, 429, 431, and 433 may be selected. In this case, four memory cells coupled to the bit line sense amplifiers 427, 429, 431, and 433 may be accessed in the row M+10. When the value of the column addresses C_ADD and C_ADD_E is 2, the bit line sense amplifiers 420, 422, 424, and 426 may be selected. In this case, four memory cells coupled to the bit line sense amplifiers 420, 422, 424, and 426 may be accessed in the row M+10. When the value of the column addresses C_ADD and C_ADD_E is 3, the bit line sense amplifiers 428, 430, 432, and 434 may be selected. In this case, four memory cells coupled to the bit line sense amplifiers 428, 430, 432, and 434 may be accessed in the row M+10. It may be seen that the bit line sense amplifiers 411 to 442 may be selected in groups of N (4 in this case), which is the number of the columns accessed at the same time.

During an error check and scrub operation, the number of the errors may be counted, and the regions classified as bad regions may be classified based on the bit line sense amplifiers 411 to 442. For example, 64 (=N*K=4*16) memory cells corresponding to the bit line sense amplifiers 419, 421, 423 and 425 may be classified as one region, and 64 memory cells corresponding to the bit line sense amplifiers 427, 429, 431 and 433 may be classified as one region. Likewise, all regions may be partitioned to include 64 memory cells corresponding to 4 bit line sense amplifiers that are accessed simultaneously.

In the case of classifying regions based on the bit line sense amplifiers 411 to 442, an error check and scrub operation may be performed as follows.

1. Error Check and Scrub Operation of a Region Including the Bit Line Sense Amplifiers 419, 421, 423, and 425

(1) The error check operation control circuit 261 may fix the value of the error check column address C_ADD_E to 0, generate an error check row address R_ADD_E so that the row M is selected, and perform a read operation. Then, 4-bit data may be output from the four memory cells coupled to the bit line sense amplifiers 419, 421, 423, and 425 in the row M.

(2) The error check operation control circuit 261 may perform read operations 15 times by changing the error check row address R_ADD_E so that the rows M+1 to M+15 are sequentially selected, while the value of the error check column address C_ADD_E is fixed to 0. Then, 60-bit data may be output from 60 memory cells that are coupled to the bit line sense amplifiers 419, 421, 423, and 425 in the rows M+1 to M+15.

(3) An error in 64-bit data read in the read operations that are performed 16 times for the memory cells coupled to the bit line sense amplifiers 419, 421, 423, and 425 may be detected by the error correction circuit 251, and the error counting circuit 263 may count the number of the errors detected in the read operations that are performed 16 times, and the result may be stored in the error log circuit 265.

2. Error Check and Scrub Operation of a Region Including the Bit Line Sense Amplifiers 427, 429, 431 and 433

(1) The error check operation control circuit 261 may fix the value of the error check column address C_ADD_E to 1, generate an error check row address R_ADD_E so that the row M+8 is selected, and perform a read operation. Then, 4-bit data may be output from the four memory cells that are coupled to the bit line sense amplifiers 427, 429, 431, and 433 in the row M+8.

(2) The error check operation control circuit 261 may perform read operations 15 times by changing the error check row address R_ADD_E so that the rows M+9 to M+23 are sequentially selected while the value of the error check column address C_ADD_E is fixed to 1. Then, 60-bit data may be output from 60 memory cells that are coupled to the bit line sense amplifiers 427, 429, 431, and 433 in the rows M+9 to M+23.

(3) An error in 64-bit data read from the read operations that are performed 16 times for the memory cells coupled to the bit line sense amplifiers 427, 429, 431, and 433 may be detected by the error correction circuit 251, and the error counting circuit 263 may count the number of the errors detected in the 16 read operations, and the result may be stored in the error log circuit 265.

When an error check operation is performed by dividing a region based on the bit line sense amplifiers, it may become easy to detect a column-related defect. For example, when many errors occur in a particular region, it may be seen that there is a defect in the column-related constituent elements, such as bit line sense amplifiers or column switches interlocking with them in the corresponding region.

According to the embodiment of the present invention, it is possible to check errors of a memory.

The effects desired to be obtained in the embodiments of the present invention are not limited to the effects mentioned above, and other effects not mentioned above may also be clearly understood by those of ordinary skill in the art to which the present invention pertains from the description below.

While the present invention has been described with respect to the specific embodiments, it will be apparent to those skilled in the art that various changes and modifications may be made without departing from the spirit and scope of the invention as defined in the following claims. Furthermore, the embodiments may be combined to form additional embodiments.

What is claimed is:

1. A method for operating a memory, the method comprising:
a first region error checking operation of reading first data from N memory cells in each of K rows by using N first bit line sense amplifiers and checking errors from the first data, each of K and N being an integer equal to or greater than 2;
processing first region error information based on a number of the checked errors from the first data;
a second region error checking operation of reading second data from N memory cells in each of K rows by using N second bit line sense amplifiers and checking errors from the second data; and
processing second region error information based on the number of checked errors from the second data.

2. The method of claim 1, wherein the first data are read from all memory cells corresponding to the N first bit line sense amplifiers.

3. The method of claim 2, wherein the second data are read from all memory cells corresponding to the N second bit line sense amplifiers.

4. The method of claim 3, wherein an N-bit data is output from the memory per one read operation of the memory, and
wherein each of the first and second bit line sense amplifiers corresponds to K memory cells.

5. The method of claim 1, wherein the first region error checking operation includes:
reading first N-bit data from the N memory cells which correspond to the first bit line sense amplifiers in a first row among the K rows corresponding to the N first bit line sense amplifiers;
checking the errors from the first N-bit data; and
repeating the reading of the first N-bit data and the checking of the errors from the first N-bit data on remaining rows of the K rows corresponding to the N first bit line sense amplifiers.

6. The method of claim 5, wherein the second region error checking operation includes:
reading second N-bit data from the N memory cells which correspond to the second bit line sense amplifiers in the first row among the K rows corresponding to the N second bit line sense amplifiers;
checking the errors from the second N-bit data; and
repeating the reading of the second N-bit data and the checking of the errors from the second N-bit data on remaining rows of the K rows corresponding to the N second bit line sense amplifiers.

7. The method of claim 1, wherein the processing of the first region error information includes storing, in a log circuit, the first region error information when the number of the checked errors from the first data is equal to or greater than a threshold value.

8. The method of claim 1, wherein the processing of the first region error information includes storing, in a log circuit, the number of the checked errors from the first data.

9. A memory comprising:
a cell array including a plurality of memory cells and including a plurality of bit line sense amplifiers, the memory cells being arranged in a plurality of rows and a plurality of columns and being grouped into a plurality of regions, and the bit line sense amplifiers suitable for sensing and amplifying data of the memory cells;
an error detection circuit suitable for detecting an error in data read from each of the regions; and
an error counting circuit suitable for counting a number of detected errors,
wherein each of the regions includes:
N bit line sense amplifiers, where N is an integer equal to or greater than 2; and
memory cells in which data is sensed and amplified by the N bit line sense amplifiers.

10. The memory of claim 9, wherein each of the regions includes all memory cells that are sensed and amplified by the bit line sense amplifiers in the corresponding region.

11. The memory of claim 9, wherein N-bit data is output from the memory per one read operation of the memory.

12. The memory of claim 9, further comprising an error log circuit suitable for storing information on the region in which the counted number of detected errors is equal to or greater than a threshold value.

13. The memory of claim 9, further comprising an error log circuit suitable for storing the number of the detected errors.

14. The memory of claim 12, wherein the error log circuit is further suitable for providing a memory controller with the information stored therein.

15. The memory of claim 9, wherein column address of all memory cells in one region are the same.
